(19) United States
(12) Patent Application Publication
(10) Pub. No.: US 2006/0108589 A1
(43) Pub. Date: May 25, 2006

(54) Semiconductor device

(75) Inventors: Kenji Fukuda, Ibaraki (JP); Tsutomu Yatsuo, Ibaraki (JP); Shnsuke Harada, Ibaraki (JP); Seiji Suzuki, Osaka (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: NATIONAL INSTITUTE OF ADVANCED UNDUST SCI & TECH, TOKYO (JP)

(21) Appl. No.: 10/523,585

(22) PCT Filed: Aug. 4, 2003
(86) PCT No.: PCT/JP03/09872

§ 371 Date: Sep. 8, 2005

(30) Foreign Application Priority Data
Aug. 5, 2002 (JP) 2002-227254

(51) Int. Cl. H01L 31/0312

(52) U.S. Cl. 257/77

(57) ABSTRACT

A semiconductor device (1) includes an n-type silicon carbide substrate (2) of a high impurity concentration, an n-type silicon carbide layer (3) of a low impurity concentration disposed on the substrate, a first n-type silicon carbide region (4) of a first impurity concentration disposed on the surface of the n-type silicon carbide layer, first p-type silicon carbide regions (5) disposed as adjoined to the opposite sides of the first n-type silicon carbide region, a second n-type silicon carbide region (6) disposed selectively from the surface through the interior of the first p-type silicon carbide region, polycrystalline silicon (7) short-circuiting the first p-type silicon carbide region (5) to the second n-type silicon carbide region (6), a gate electrode (8) and a third n-type silicon carbide region (10), wherein the components thereof are individually constructed in a vertical DMOS structure. Since the polycrystalline silicon short-circuits the first p-type silicon carbide region to the second n-type silicon carbide region, the threshold voltage can be given a fixed value, and the device can be used as an actual MISFET.

### TECHNICAL FIELD

This invention relates to a semiconductor device using silicon carbide as a semiconductor material and including a metal-insulating film-semiconductor field effect transistor (MISFET) called a vertical DMOS structure.

### BACKGROUND ART

Since silicon carbide (SiC) has a wide band gap and has a maximum dielectric breakdown field larger by about one order than silicon (Si), this material is expected to be applied to power semiconductor devices. Among other power semiconductor devices, the MISFET of the vertical DMOS structure is expected to provide extremely low-loss high-speed power devices which surpass the performance of the Si power devices because the value of the resistance thereof in the on-state (on-resistance) is expected theoretically to be lower by about two orders than the Si MOSFET.

The MISFET using SiC, however, is known to reveal poor quality of the interface between the gate insulating film and SiC and extreme smallness of the channel mobility. For example, J. A. Cooper et al. (Mat. Res. Soc. Proc., Vol. 572, pp. 3-14) have been trying to lower the activating annealing temperature of a p-type impurity with a view to lowering the on-resistance of the MISFET of the vertical DMOS structure, but have barely improved the channel mobility to a level of about 20 to 25 cm²/Vs. Since the channel resistance is consequently high, their effort has not yet succeeded in lowering the on-resistance of the MISFET.

As one of the means to efficiently lower the channel resistance, the curtailment of the channel length proves effective. This means, however, results in suffering the punch through phenomenon to gain in conspicuousness and deteriorating the reverse direction blocking voltage of the MISFET. Precisely, the on-resistance and the reverse direction blocking voltage of the power MISFET are in a trade-off relationship. Thus, the desirability of inventing a device structure which reconciles these factors with a favorable characteristic property has been finding recognition.

The MISFET of a vertical DMOS structure is disclosed in FIG. 2 of M. A. Capano et al. (Journal of Applied Physics, Vol. 87 (2000), pp. 8773-8777) and in FIG. 1 of R. Kumar et al. (Japanese Journal of Applied Physics, Vol. 39 (2000), pp. 2001-2007). The articles of M. A. Capano et al. and R. Kumar et al. contributed to the literature, have no mention of any structural device for exaltation of blocking voltage, any buried channel structure meeting the need to lower the on-resistance, or any method for establishing contact between the P-well and a source region.

The actual MISFET of the vertical DMOS structure using a silicon carbide substrate has low channel mobility and incurs difficulty in acquiring an ideal blocking voltage as described above. Thus, a device which possesses a high blocking voltage property making the most of the physical properties of SiC and a low on-resistance resistance as well has not been realized.

This invention has been initiated in view of the true state of affairs mentioned above and is aimed at providing, in the MISFET of the vertical DMOS structure using a silicon carbide substrate, a semiconductor device which is enabled to acquire an excellent reverse direction blocking voltage property and lower the on-resistance by optimizing the source structure and the blocking voltage structure and also optimizing the surface orientation of the silicon carbide substrate.

### DISCLOSURE OF THE INVENTION

The semiconductor device contemplated by this invention comprises an n-type silicon carbide substrate of a high impurity concentration, an n-type silicon carbide layer of a low impurity concentration disposed on the substrate, a first n-type silicon carbide region of a first impurity concentration disposed on the surface of the n-type silicon carbide layer, first p-type silicon carbide regions adjoining the opposite sides of the first n-type silicon carbide region, a second n-type silicon carbide region of a second impurity concentration disposed selectively from the surface through the interior of the first p-type silicon carbide region at a position separated from the first n-type silicon carbide region, polycrystalline silicon having metal or impurity implanted therein and serving to short-circuit the first p-type silicon carbide region to the second n-type silicon carbide region, a gate electrode disposed in the surface part of the first p-type silicon abide region through a gate insulating film, and a third n-type silicon carbide region of a third impurity concentration disposed selectively from the surface through the interior of the first p-type silicon carbide region either between the first n-type silicon carbide region and the first p-type silicon carbide region below the gate electrode or between the second n-type silicon carbide region and the first p-type silicon carbide region below the gate electrode, or both, and has these components formed in a vertical DMOS structure.

In the semiconductor device of this invention, the first p-type silicon carbide region has a lower part formed as a second p-type silicon carbide region of a higher impurity concentration than the first p-type silicon carbide region.

The first mentioned semiconductor device of this invention further comprises an n-type silicon carbide region formed selectively from the surface through the interior of the first p-type silicon carbide region below the gate electrode, wherein the n-type silicon carbide region has an impurity concentration enough for serving as a buried channel region and has a layer thickness which is 0.2 to 1.0 times the layer thickness of the second n-type silicon carbide region.

In the third mentioned semiconductor device of this invention, the buried channel region has an impurity concentration in the range of 5×10¹⁵ to 1×10¹⁷ cm⁻³.

In any one of the first to fourth mentioned semiconductor devices of this invention, the gate electrode is formed of aluminum, an aluminum-containing alloy or molybdenum.

In any one of the first to fourth mentioned semiconductor devices of this invention, the gate electrode is formed of p-type polycrystalline silicon having boron doped therein at a concentration in the range of 1×10¹⁶ to 1×10²¹ cm⁻³.

In any one of the first to fourth mentioned semiconductor devices of this invention, the gate electrode is formed of n-type polycrystalline silicon having phosphorus or arsenic implanted therein at a concentration in the range of 1×10¹⁶ to 1×10²¹ cm⁻³.

Any one of the first to fourth mentioned semiconductor devices of this invention further comprises a silicide film superposed on the gate electrode, wherein the silicide film is formed of silicon and any one of tungsten, molybdenum and titanium.

In any of the first to fourth mentioned semiconductor devices of this invention, the n-type substrate of the high impurity concentration is formed of a hexagonal Or rhombohedral silicon carbide single crystal, and the n-type silicon carbide layer of the low impurity concentration is formed on a (11-20) face or a (000-1) face of the n-type substrate.

The semiconductor device contemplated by this invention is enabled by being constructed as described above to acquire improved channel mobility, retain the threshold voltage at a fixed value, attain an ideal blocking voltage and permit provision of a MISFET suitable for practical use.

### BRIEF DESCRIPTION OF THE DRAWINGS

FIG. 1 is a diagram schematically illustrating a cross section of the semiconductor device according to the first embodiment of this invention.

FIG. 2 is a diagram schematically illustrating a cross section of the semiconductor device according to the second embodiment of this invention.

FIG. 3 is a diagram schematically illustrating a cross section of the semiconductor device according to the third embodiment of this invention.

FIG. 4 is a diagram schematically illustrating a cross section of the semiconductor device according to the fourth embodiment of this invention.

FIG. 5 is a diagram showing the dependency of the channel mobility of a sample of Example 4 on Lbc+Xj (Lbc/Xj).

FIG. 6 is a diagram showing the relation between the impurity concentration and the channel mobility of a buried channel region of the sample of Example 4.

FIG. 7 is a diagram showing the relation between the impurity concentration and the threshold voltage of a gate electrode of the sample of Example 4.

### BEST MODE OF EMBODYING THE INVENTION

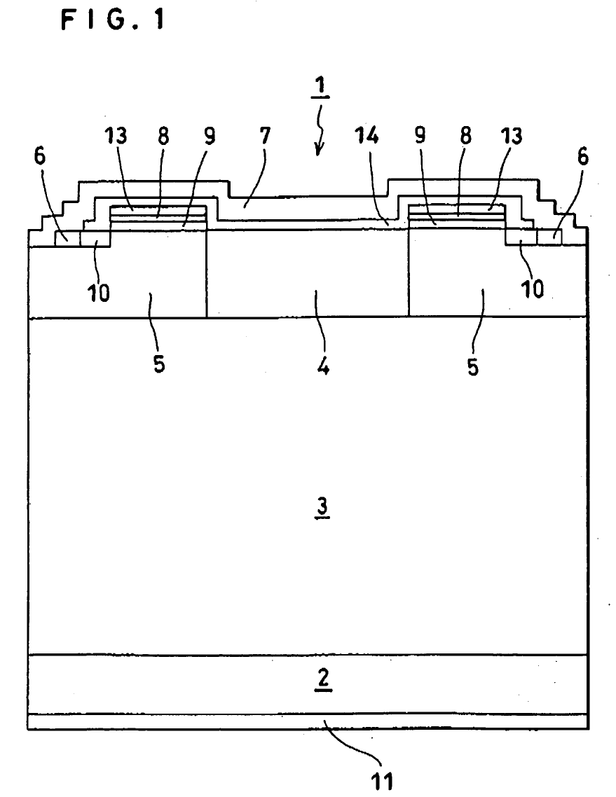

FIG. 1 is a diagram schematically illustrating a cross section of the semiconductor device according to the first embodiment of this invention. With reference to FIG. 1, a semiconductor device 1 is a metal-insulating film-semiconductor field effect transistor (MISFET) of a vertical DMOS structure using a silicon carbide substrate and it is composed of an n-type silicon carbide substrate 2 of a high impurity concentration, an n-type silicon carbide layer 3 of a low impurity concentration disposed thereon, and the individual components superposed thereon.

Specifically, on the surface of the n-type silicon carbide layer 3, a first n-type silicon carbide region (N⁻ layer) 4 of a first impurity concentration is formed at the center and first p-type silicon carbide regions (p-type (P-)wells) 5, 5 are formed as adjoined respectively to the opposite sides of the first n-type silicon 4.

Then, in the first p-type silicon carbide regions 5, 5, second n-type silicon carbide regions (N⁺ sources) 6, 6 of a second impurity concentration are formed selectively from the surface through the interior of the first p-type silicon carbide regions 5, 5 at positions separated from the first n-type silicon carbide region 4. Also, a metallic wiring 7 formed of aluminum, copper or an alloy thereof is laid so as to short-circuit the first p-type silicon carbide regions 5 to the second n-type silicon carbide regions 6.

Further, gate electrodes 8, 8 are formed in part of the surfaces of the first p-type silicon carbide regions 5, 5 through gate insulating films (gate oxide films) 9, 9. Then, a drain electrode 11 is formed on the rear side of the n-type silicon carbide substrate 2.

In the first p-type silicon carbide regions 5, 5 between the second n-type silicon carbide regions (N⁺ sources) 6, 6 and the first p-type silicon carbide regions (P-wells) 5, 5 below the gate electrodes 8, 8, third n-type silicon carbide regions (N⁻ regions) 10, 10 are formed selectively from the surface through the interior thereof. The individual parts 1 to 10 mentioned above are formed in a vertical DMOS structure.

In the semiconductor device 1 of the structure mentioned above, when the first p-type silicon carbide regions (P-wells) 5 and the second n-type silicon carbide regions (N⁺ sources) 6 are not short-circuited, the threshold voltage is not fixed and the MISFET cannot be actually used because the first p-type silicon carbide regions 5 and the second n-type silicon carbide regions 6 are in an electrically floated state. In the present invention, since the first p-type silicon carbide regions (P-wells) 5 and the second n-type silicon carbide regions (N⁺ sources) 6 are short-circuited by the use of the metallic wiring 7, the threshold voltage is fixed and the MISFET can be actually used. The term “threshold voltage” as used herein refers to a gate voltage which exists when the MISFET reaches on-state.

Then, in this invention, the third n-type silicon carbide regions (N⁻ regions) 10 are formed in the first p-type silicon carbide regions (P-wells) 5 between the second n-type silicon carbide regions (N⁺ sources) 6 and the first p-type silicon carbide regions (P-wells) 5 below the gate electrodes 8 and the third n-type silicon carbide regions 10 are interposed between the gate electrodes 8 and the first p-type silicon carbide regions 5. Thus, the third n-type silicon carbide regions 10 are enabled to relax the electric field exerted on the gate electrodes (gate channel regions) 8 and prevent the gate parts from yielding to the electric field and consequently exalt the blocking voltage between the drain electrode 11 and the second n-type silicon carbide regions (N⁺ sources) 6. Further, the hot carrier lifetime elongated and the effect thereof can be confirmed.

Here, the hot carrier lifetime will be described. The phenomenon in which electrons flowing from the source to the drain are injected in a high energy state from a semiconductor into an oxide film is called “a hot carrier phenomenon.” When the hot carrier phenomenon occurs, the threshold voltage is varied because an electric charge is accumulated in the oxide film. Generally, when the amount of the variation of the threshold voltage is measured while an operating voltage is being applied, the time which elapses till the variation reaches 10% of the initial value is defined as the hot carrier lifetime. In this embodiment, since the third n-type silicon carbide regions 10 have a low impurity concentration, the electric field is relaxed, and the electrons are not easily allowed to assume a high energy state, the hot carrier phenomenon is suppressed and the hot carrier lifetime is elongated.

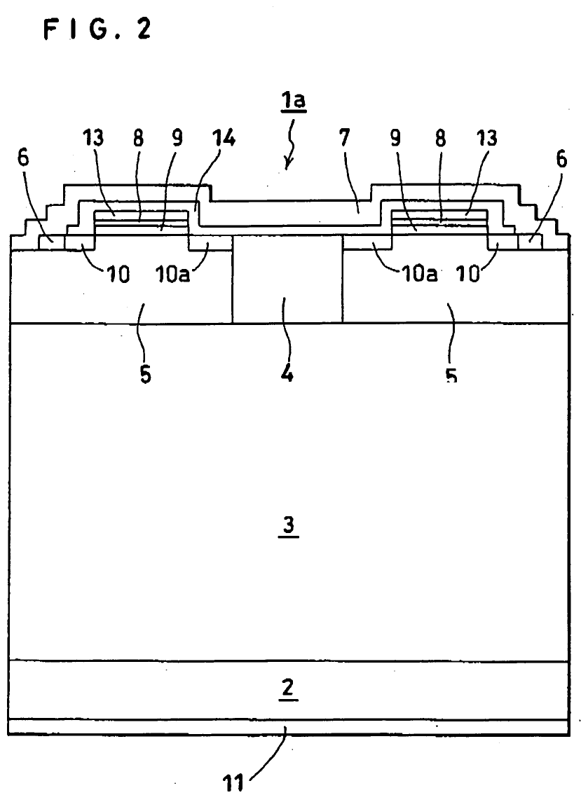

FIG. 2 is a diagram schematically illustrating a cross section of the semiconductor device according to the second embodiment of this invention. In FIG. 2, the same component elements as in the first embodiment will be denoted by the same numerical symbols and they will be omitted from the following description. A semiconductor device la in the second embodiment differs from the first embodiment in respect that a third n-type silicon carbide region (N⁻ region) 10a is intended to be formed in addition to the third n-type silicon carbide region (N⁻ region) 10. Specifically, the third n-type silicon carbide region 10a of a third impurity concentration is formed selectively from the surface through the interior of the first p-type silicon carbide region 5 between the first n-type silicon carbide region (N⁻ layer) 4 and the first p-type silicon carbide region 5 below the gate electrode 8.

Thus, in the second embodiment, the N⁻ regions 10, 10a are respectively interposed between the gate electrodes 8 and the first p-type silicon carbide regions 5 and between the gate electrodes 8 and the first n-type silicon carbide regions 4. The semiconductor device 1a, therefore, is capable of better preventing the gate parts from yielding to an electric field and is capable of exalting more the blocking voltage between the drain electrode 11 and the second n-type silicon carbide regions (S sources) 6 than the semiconductor device 1 of the first embodiment. It has been also made possible to uniformize further the resistance of the gate channel region between the two gate electrodes (cells) 8, 8, prevent the occurrence of local current concentration and allay the on-resistance as a whole.

Though the foregoing description has depicted the provision of both the third n-type silicon carbide regions (N⁻ regions) 10 and 10a, it is permissible to use only the third n-type silicon carbide region (N⁻ region) 10a alone in the structure. Even this structure is capable of manifesting the effect of exalting the blocking voltage between the drain electrode 11 and the second n-type silicon carbide region (N⁺ source) 6,

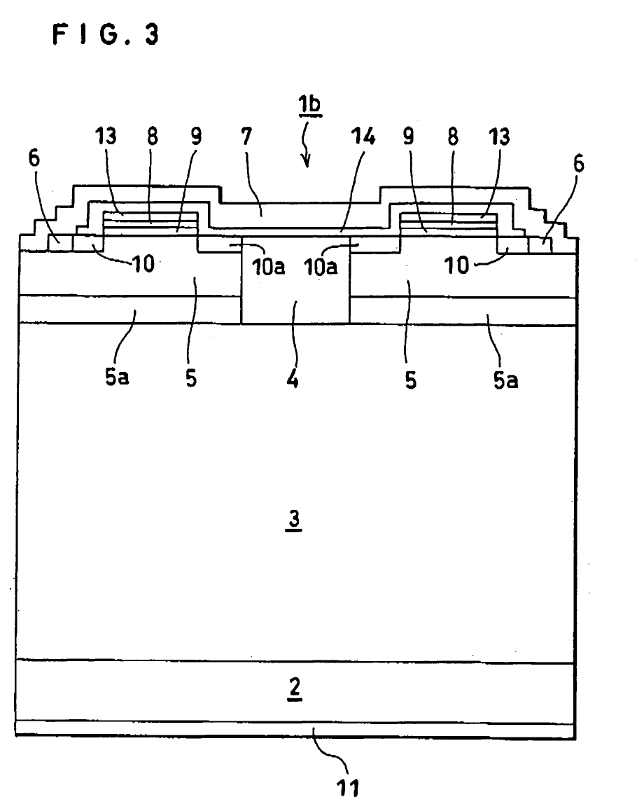

FIG. 3 is a diagram schematically illustrating a cross section of the semiconductor device according to the third embodiment of this invention. In FIG. 3, the same component elements as in the first and second embodiments will be denoted by the same reference numerals and will be omitted from the following description. A semiconductor device 1b of this third embodiment differs from the second embodiment in respect that the lower part of the first p-type silicon carbide region 5 is formed as a second p-type silicon carbide region 5a of a higher concentration than the first p-type silicon carbide region 5. Since the third embodiment forms the lower part of the first p-type silicon carbide region 5 in a higher impurity concentration as described above, it is enabled to acquire a further improved blocking voltage property.

By shortening the depletion layer from the second p-type silicon carbide region 5a, thereby rendering contact with the depletion layer from the source region 6 difficult, it has been made possible to suppress the possibility of the application of a high voltage forming a high electric field between the source region 6 and the n-type silicon carbide layer 3 and, as a result, exalting the blocking voltage property.

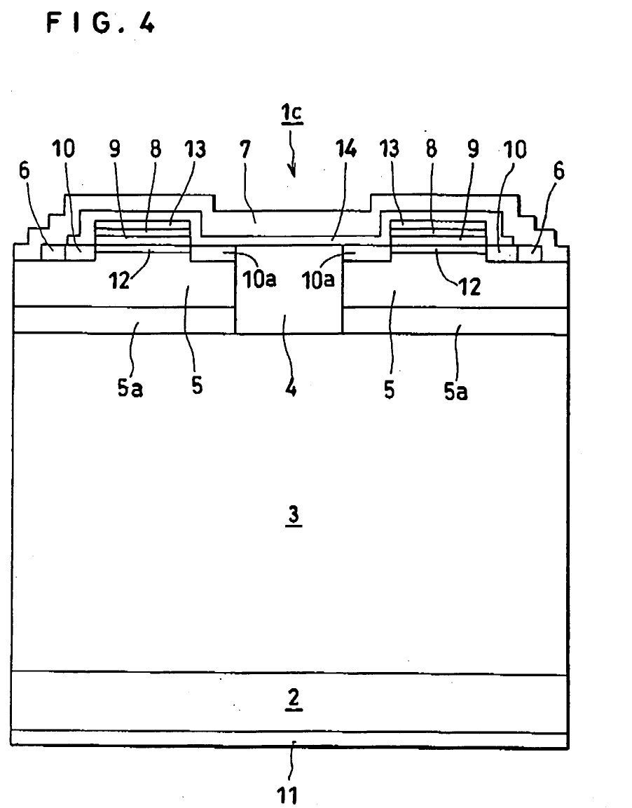

FIG. 4 is a diagram schematically illustrating a cross section of the semiconductor device according to the fourth embodiment of this invention. In FIG. 4, the same component elements as in the first, second and third embodiments will be denoted by the same referential numerals and will be omitted from the following description A semiconductor device 1c of this fourth embodiment differs from the third embodiment in respect that a buried channel region 12 is formed as an n-type silicon carbide region possessing a sufficient impurity concentration selectively from the surface through the interior of the first p-type silicon carbide region 5 below the gate electrode 8. Owing to the provision of the buried channel region 12, the fourth embodiment is enabled to heighten the channel mobility and lower the on-resistance value.

Now, the process for the production of the semiconductor device 1c of the fourth embodiment will be roughly described below. In this invention, hexagonal silicon carbide or rhombohedral silicon carbide was adopted for the n-type silicon carbide substrate 2 of the high impurity concentration and an n-type silicon carbide layer 3 of a low impurity concentration was formed on the (11-20) face of the hexagonal silicon carbide or rhombohedral silicon carbide.

Next, on the n-type silicon carbide layer 3, the first n-type silicon carbide region (N⁻ layer) 4 formed of silicon carbide possessing a first impurity concentration was epitaxially grown by the chemical vapor deposition method. Subsequently, the substrate formed of silicon carbide at this stage was given an ordinary RCA cleaning and thereafter an alignment mark for lithography was formed thereon by RIE (reactive ion etching).

Then, an LTO (low temperature oxide) film was used as a mask for ion implantation. This LTO film was formed by reacting silane with oxygen at 400° C. to 800° C., thereby depositing silicon dioxide on a silicon carbide substrate. Next, a region for ion implantation was formed by lithography and the LTO film was etched with HF (hydrofluoric acid) to open the region for ion implantation. Subsequently, by ion-implanting aluminum or boron into the first n-type silicon carbide region (N⁻ layer) 4, the first p-type silicon carbide regions (p-type wells) 5, 5 were formed as adjoined to the opposite sides of the first n-type silicon carbide region (N⁻ layer) 4.

Further, by ion implantation aimed at heightening the blocking voltage, a second p-type silicon carbide region (P⁺ region) 5a of a higher impurity concentration than the first p-type silicon carbide region 5 was formed in the lower part of the first p-type silicon carbide region 5. Then, it was found that the blocking voltage property could be infallibly improved by having the second p-type silicon carbide region Sa formed by implantation of 10¹⁸ to 10¹⁹ cm⁻³ of aluminum or boron.

Further, the buried channel region 12 was formed as an n-type silicon carbide region possessing a sufficient impurity concentration selectively from the surface through the interior of the first p-type silicon carbide region 5 below the gate electrode 8. This buried channel region 12 was formed by implanting 1×10¹⁵ to 5×10¹⁷ cm⁻³ of ions at a depth (Lbc) of 0.3 μm.

Next, the second n-type silicon carbide regions (N⁺ sources) 6, 6 of a second concentration were formed selectively from the surface through the interior of the first p-type silicon carbide regions 5, 5 as separated from the first n-type silicon carbide region 4.

Further, between the second n-type silicon carbide regions (N⁺ sources) 6, 6 and the first p-type silicon carbide regions 5, 5 below the gate electrodes 8, 8 destined to be formed in part of the surfaces of the first p-type silicon carbide regions 5, 5 at a subsequent step, the third n-type silicon carbide regions 10, 10 of a third concentration were formed by ion implantation selectively from the surface through the interior of the first p-type silicon carbide regions 5, 5.

Thereafter, the ensuing composite was subjected to an activating anneal in the atmosphere of argon at 1500° C.. Subsequently, it was oxidized at 1200° C. to form the gate oxide films 9, 9 about 50 nm in thickness. It was then annealed in the atmosphere of argon for 30 minutes and cooled in the atmosphere of argon to room temperature. Thereafter, the gate electrodes 8, 8 were formed. The gate electrodes 8, 8 were formed of P⁺ polysilicon. The formation of the gate electrodes 8, 8 of P⁺ polysilicon may be accomplished, for example, by 1) a method for accomplishing formation of the p-type polycrystalline silicon by forming a polycrystalline polysilicon by the CVD process and subsequently ion implantation of boron or boron fluoride into the polycrystalline polysilicon, 2) a method for attaining formation of the p-type polycrystalline silicon by forming a polycrystalline polysilicon by the CVD process and subsequently forming a boron-containing SiO₂ film by the CVD process or the spin-coating process and heat-treating the film at 800° C. to 1100° C. till diffusion and consequently effecting implantation of the boron and 3) a method for effecting formation of the p-type polycrystalline silicon by continuing a simultaneous flow of silane and diborane and heat-treating this flow at 600° C., thereby doping boron into the polycrystalline silicon. The present embodiment adopted the method of 2). Then, the formation of the gate electrodes 8, 8 was completed by etching the resultant composite.

Though the preceding description has presumed to form the gate electrode 8 of P⁻ polysilicon, the gate electrode 8 may be formed of N⁺ polysilicon, aluminum, an aluminum alloy or molybdenum. It has been confirmed that when the gate electrode 8 is formed of aluminum, an aluminum alloy or molybdenum, the interface thereof with the gate oxide film 9 excels the interface with the gate oxide film 9 using polysilicon for the gate electrode 8 and brings the effect of exalting the channel mobility.

Either of the gate electrodes 8, 8 had an element possessing a silicide film 13 of WSi₂, MoSi₂ or TiSi₂ formed on the N⁺ or P⁺ polysilicon.

Subsequently, interlayer insulating films 14 were deposited by the CVD process and the interlayer insulating films 14 on the second n-type silicon carbide layers (N⁺ sources) 6, 6 and the first p-type silicon carbide regions (P-wells) 5, 5 were etched to open contact holes. Then, a film of nickel, titanium, aluminum or an alloy thereof was deposited by evaporation or by the spattering process, contacts were formed therein by RIE or by the wet etching process, and the metallic wiring 7 of an alloy containing aluminum or copper was firer formed thereon, thereby short-circuiting the first p-type silicon carbide region 5 to the second n-type silicon carbide region 6.

In the present embodiment, the metallic wiring 7 was formed by vacuum-depositing aluminum and nickel, forming contacts therein by a wet etching process, then vacuum-depositing aluminum thereon, and wet-etching the resultant component.

Next, on the rear side of the n-type silicon carbide substrate 2, the drain electrode 11 was formed by attaching a metal thereto by the vacuum deposition process or the spattering process to a necessary thickness. In the present embodiment, the drain electrode 11 was formed by spattering nickel. Optionally, the resultant composite was heat-treated in the atmosphere of argon at 1000° C. for five minutes. Thus, an MIS field effect transistor of a vertical DMOS structure was completed.

In the preceding fourth embodiment, the following samples were prepared and tested with the object of clarifying various characteristic properties.

First, the second p-type silicon carbide region 5a of a high concentration formed in the lower part of the first p-type silicon carbide region 5 by the ion implantation process was examined to determine the upper limit and the lower limit of impurity concentration As a result, it was found that when the impurity concentration of the second p-type silicon carbide region (P⁺ region) 5a was lower than 1×10¹⁷ cm⁻³, the voltage causing dielectric breakdown was the same as in the absence of this P⁺ region, indicating that the region was ineffective, that when the impurity concentration was or exceeded 1×10¹⁷ cm⁻³, the voltage causing dielectric breakdown was increased, and therefore that the lower limit of the impurity concentration was 1×10¹⁷ cm⁻³. It was meanwhile found that when the impurity concentration exceeded 1×10¹⁹ cm⁻³, the impurity was diffused during the course of the subsequent activating anneal, eventually cancelled the n-type impurity in the overlying buried channel 12 and consequently prevented the buried channel 12 from fulfilling the effect thereof and therefore that the upper limit was 1×10¹⁹ cm⁻³.

Next, buried channel regions 12 having depths, Lbe, of 0.1, 0.2, 0.3, 0.4, 0.5 and 1.0 μm were formed with the object of investigating the relation between the ratio (Lbc/Xj) of the depth Lbc of the buried channel region 12 to the depth Xj of the second n-type silicon carbide region (N⁺ source) 6 and the channel mobility.

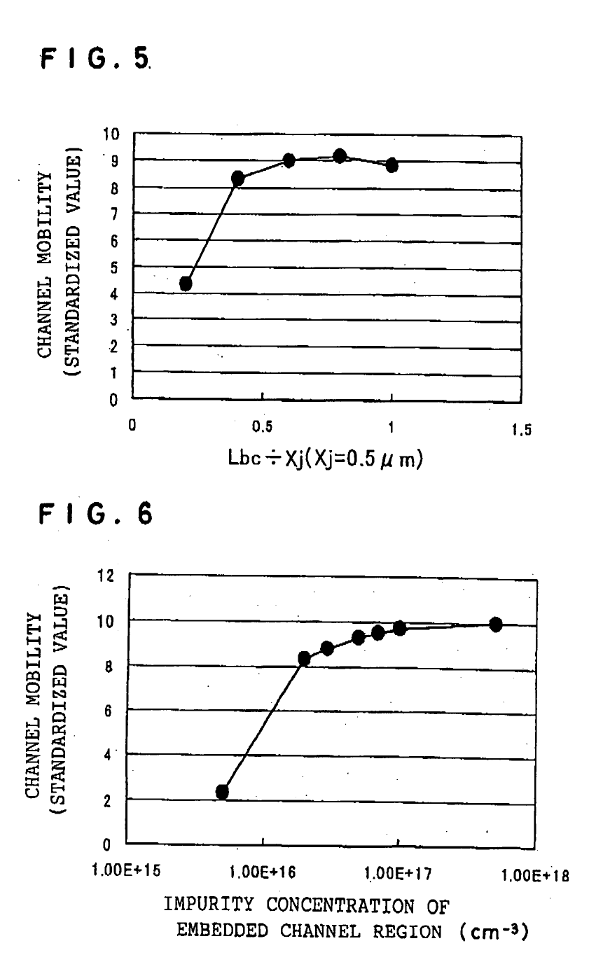

FIG. 5 shows the dependency of the channel mobility on the quotient Lbc÷Xj (Lbc/Xj) at the depth Xj of 0.5 μm. In FIG. 5, the channel mobility is standardized with the channel mobility which exists when the buried channel 12 is not provided& That is, the channel mobility is 1 in the absence of the buried channel region 12. The evaluation was carried out with the depth Lbc of the buried channel region 12 fixed at 0.1, 0.2, 0.3, 0.4, 0.5 and 1.0 μm. The channel mobility was 4.3 when the depth Lbc was 0.1 μm (Lbc/Xj=0.2) and the channel mobility was 8.4 when the depth Lbc was 0.2 μm (Lbc/Xj=0.4), indicating that the buried channel region 12 was effective even when the thickness Lbc was 0.1 μm. Meanwhile, the thickness Lbc exceeding 1.0 μm (Lbc/Xj=2) could be actually used only with difficulty because the overage imparted a negative value or normally ON to the threshold in spite of an increase in the channel mobility. Thus, the depth Lbc of the buried channel region 12 had a lower limit of 0.1 μm and an upper limit of 1.0 μm. This range corresponds to a range of 0.2 to 2.0 in Lbc/Xj. Particularly, the range of 0.2 to 1.0 proves advantageous.

Subsequently, samples having undergone ion implantation to degrees in the range of 5×10¹⁵ to 5×10¹⁷ cm⁻³ were prepared with the object of investigating the concentration dependency of the buried channel 12 relative to the channel mobility.

FIG. 6 is a diagraph showing the relation between the impurity concentration and the channel mobility in the buried channel region. The channel mobility was standardized with the channel mobility which existed when the buried channel region 12 was not provided as in the case of FIG. 5. That is, the channel mobility was 1 when the buried channel region 12 was not provided. Since the buried channel region was satisfactorily effective at the lowest value of impurity concentration, 5×10¹⁵ cm⁻³, used for the evaluation, the lower limit of the impurity concentration was fixed at 5×10¹⁵ cm⁻³. Meanwhile, since the value exceeding 5×10¹⁷ cm⁻³ produced a negative threshold voltage and rendered actual use of the produced device difficult, the upper limit of this value was fixed at 5×10¹⁷ cm⁻³.

In the present embodiment, the gate electrode 8 made of p-type polycrystalline silicon (P⁺ polysilicon) was obtained by forming polycrystalline polysilicon by the CVD process, then forming a boron-containing SiO₂ film by the CVD process or the spin coating and heat-treating the resultant composite at 800° C. to 1100° C., thereby diffusing boron and doping boron as described above. Samples having impurity concentration varied from 1×10¹⁵ through 1×10²¹ cm⁻³ were prepared by performing the heat treatment at 900° C. for varying lengths of diffusion time with the object of investigating the relation between the impurity concentration and the threshold voltage of the gate electrode 9 and these samples were tested for threshold voltage.

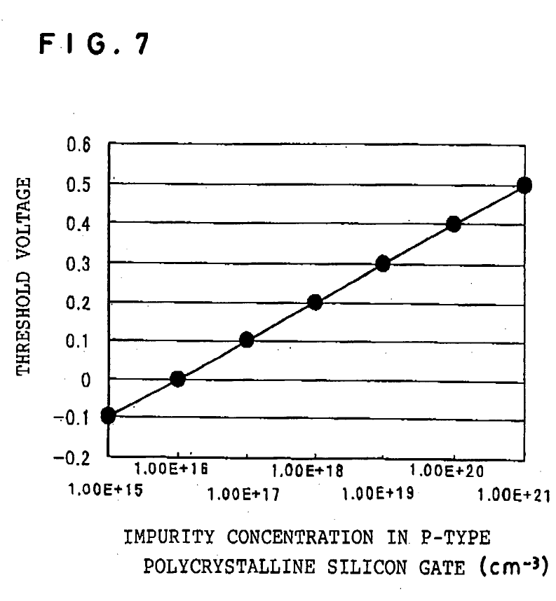

FIG. 7 is a diagram showing the relation between the impurity concentration and the threshold voltage of the gate electrode. It is noted from FIG. 7 that the difference of work function between the gate electrode and the semiconductor increases and consequently the threshold increases in proportion as the impurity concentration in the gate electrode 8 increases. Conversely, the threshold voltage decreased proportionately with the decrease of the impurity concentration and reached a zero at an impurity concentration of 1×10¹⁶ cm⁻³. Thus, the lower limit of the impurity concentration was fixed at 1×10¹⁶ cm⁻³. Meanwhile, since the concentration to which boron could be implanted into the polycrystalline silicon was 1×10²¹ cm⁻³, the upper limit of the impurity concentration was fixed at 1×10²¹ cm⁻³.

In the fourth embodiment, silicide films 13 of WSi₂, MoSi₂ or TiSi₂ were also formed on the gate electrodes 8, 8. While the resistance of the gate electrode 8 made of the polycrystalline silicon having boron implanted to a high concentration therein was several mΩcm, the relative resistances of the WSi₂, MoSi₂ and TiSi₂ each forming the silicide film 13 were respectively 60 μΩcm, 50 μΩcm and 15 μΩcm. The composite film of polycrystalline silicon and silicide, therefore, could lower the resistance of the gate electrode than the gate electrode formed solely of polycrystalline silicon. In the fourth embodiment, the driving force of the MIS field-effect semiconductor device could be improved.

Further, in the fourth embodiment, the n-type silicon carbide layer 3 was formed on the (0001) face, (11-20) face and (000-1) face of the tetragonal or rhombohedral silicon carbide layer having a high impurity concentration. The DMOS suture MISFET illustrated in FIG. 3 was also manufactured on these faces and tested for on-resistance. The blocking voltage was designed to be 1 kV. The channel mobility of the MISFET was 45 cm²/Vs on the (0001) face, 201 cm²/Vs on the (11-20) face and 127 cm²/Vs on the (000-1) face. Since the dielectric breakdown field on the (11-20) face was about 70% of that on the (0001) face or the (000-1) face, the value of on-resistance was 33 mΩcm² on the (0001) face, 5 mΩcm² on the (11-20) face and 2 mΩcm² on the (000-1) face, that on the (000-1) face being lowest. By using the (11-20) face or the (000-1) face in comparison with the (0001) face which is generally used, therefore, it is made possible to provide DMOS structure MISFETs which possess a low on-resistance.

### INDUSTRIAL APPLICABILITY

The semiconductor device contemplated by this invention is enabled by short-circuiting the first p-type silicon carbide region to the second n-type silicon carbide region with the polycrystalline silicon having a metal or an impurity implanted therein to impart a fixed value to the threshold voltage and use the device as an actual MISFET.

Further, since the semiconductor device according to this invention has the third n-type silicon carbide region disposed either between the first n-type silicon carbide region and the first p-type silicon carbide region below the gate electrode or between the second n-type silicon carbide region and the first p-type silicon carbide region below the gate electrode, or both, selectively from the surface through the interior of the first p-type silicon carbide region, it is capable of preventing the gate part of the third n-type silicon carbide region from yielding to the electric field and consequently exalting the blocking voltage between the drain electrode and the second n-type silicon carbide region (N⁺ source) and elongating the lifetime of the hot carrier as well.

Since the first p-type silicon carbide region has the lower part thereof formed as the second p-type silicon carbide region having a higher concentration than the first p-type silicon carbide region, it is enabled to exalt the blocking voltage property thereof further.

Further, since the buried channel region is formed selectively from the surface through the interior of the first p-type silicon carbide region below the gate electrode, the channel mobility can be improved and the value of the on-resistance can be lowered.

Since the impurity concentration of the buried channel region is limited within the range of 5×10¹⁵ to 1×10¹⁷ cm⁻³, the channel mobility can be infallibly improved to several times.

Since the gate electrode is formed of aluminum, an aluminum-containing alloy or molybdenum, the interface thereof with the gate oxide film can be enhanced and the channel mobility can also be improved.

Further, since the gate electrode is formed of a p-type polycrystalline silicon having boron implanted therein to a concentration in the range of 1×10¹⁶ to 1×10²¹ cm⁻³, the threshold voltage which varies proportionately with the impurity concentration in the gate electrode can be properly retained.

Since the gate electrode is formed of an n-type polycrystalline silicon having phosphorus or arsenic implanted therein to a concentration in the range of 1×10¹⁶ to 1×10²¹ cm⁻³, it is made possible to perform a high-temperature heat treatment at not lower than 1,000° C. even after the formation of the gate electrode and exalt the characteristic properties of the MIS field-effect semiconductor device.

Since the silicide film formed of silicon and any one of tungsten, molybdenum and titanium is deposited on the gate electrode, the value of the resistance of the gate electro can be lowered below that of the gate electrode formed solely of polycrystalline silicon, and the driving force of the MIS field-effect semiconductor device can be improved.

Further, since the n-type silicon carbide layer of a low impurity concentration is formed on the (000-1) face and the (11-20) face of the n-type substrate of a high impurity concentration which is formed of a tetragonal or rhombohedral single crystal, the channel mobility can be improved and the value of the on-resistance can be lowered.

1. A semiconductor device comprising:.
an n-type silicon carbide substrate (2) of a high impurity concentration,
an n-type silicon carbide layer (3) of a low impurity concentration disposed on the substrate;
a first n-type silicon carbide region (4) of a first impurity concentration disposed on a surface of said n-type silicon carbide layer of the low impurity concentration;
first p-type silicon carbide regions (5) disposed as adjoined to opposite sides of said first n-type silicon carbide region;
a second n-type silicon carbide region (6) of a second impurity concentration disposed selectively from a surface through an interior of said first p-type silicon carbide region at a position separated from said first n-type silicon carbide region;
polycrystalline silicon (7) having a metal or an impurity implanted therein and serving to short-circuit said first p-type silicon carbide region to said second n-type silicon carbide region;
a gate electrode (8) disposed in a surface part of said first p-type silicon carbide region through a gate insulating film (9); and
a third n-type silicon carbide region (10) of a third impurity concentration formed either between said first n-type silicon carbide region and the first >type silicon carbide region below said gate electrode or between said second n-type silicon carbide region and the first p-type silicon carbide region below the gate electrode, or both, selectively from the surface through the interior of the first p-type silicon carbide region;
all components being individually formed in a vertical DMOS structure.

2. A semiconductor device according to claim 1, wherein said first p-type silicon carbide region (5) has a lower part formed as a second p-type silicon carbide region (5a) of a higher impurity concentration than said first p-type silicon carbide region.

3. A semiconductor device according to claim 1, further comprising an n-type silicon carbide region (10a) formed selectively from the surface through the interior of the first p-type silicon carbide region below said gate electrode (8), wherein the n-type silicon carbide region has an impurity concentration sufficient to produce a buried channel region and the buried channel region is formed in a layer thickness 0.2 to 1.0 times a layer thickness of the second n-type silicon carbide region.

4. A semiconductor device according to claim 2, further comprising an n-type silicon carbide region (10a) formed selectively from the surface through the interior of the first p-type silicon carbide region below said gate electrode (8), wherein the n-type silicon carbide region has an impurity concentration sufficient to produce a buried channel region and the buried channel region is formed in a layer thickness 0.2 to 1.0 times a layer thickness of the second n-type silicon carbide region.

5. A semiconductor device according to claim 3 or claim 4, wherein said buried channel region has an impurity concentration in the range of 5×10¹⁵ to 1×10¹⁷ cm⁻³.

6. A semiconductor device according to any one of claims 1 to 4, wherein said gate electrode (8) is formed of aluminum, an aluminum-containing alloy or molybdenum.

7. A semiconductor device according to any one of claims 1 to 4, wherein said gate electrode (8) is formed of a p-type polycrystalline silicon having boron implanted therein to a concentration in the range of 1×10¹⁶ to 1×10²¹ cm⁻³.

8. A semiconductor device according to any one of claims 1 to 4, wherein said gate electrode (8) is formed of an n-type polycrystalline silicon having phosphorus or arsenic implanted therein to a concentration in the range of 1×10¹⁶ to 1×10²¹ cm³.

9. A semiconductor device according to any one of claims 1 to 4, further comprising a silicide film (13) deposited on said gate electrode (8), wherein the silicide film is formed of silicon and any one of tungsten, molybdenum and titanium.

10. A semiconductor device according to any one of claims 1 to 4, wherein said n-type silicon carbide layer (3) of a low impurity concentration is formed on a (11-20) face of the n-type substrate (2) of a high impurity concentration made of a tetragonal or rhombohedral silicon carbide single crystal.

11. A semiconductor device according to claim 5, wherein said n-type silicon carbide layer (3) of a low impurity concentration is formed on a (11-20) face of the n-type substrate (2) of a high impurity concentration made of a tetragonal or rhombohedral silicon carbide single crystal.

12. A semiconductor device according to claim 6, wherein said n-type silicon carbide layer (3) of a low impurity concentration is formed on a (11-20) face of the n-type substrate (2) of a high impurity concentration made of a tetragonal or rhombohedral silicon carbide single crystal.

13. A semiconductor device according to claim 7, wherein said n-type silicon carbide layer (3) of a low impurity concentration is formed on a (11-20) face of the n-type substrate (2) of a high impurity concentration made of a tetragonal or rhombohedral silicon carbide single crystal.

14. A semiconductor device according to claim 8, wherein said n-type silicon carbide layer (3) of a low impurity concentration is formed on a (11-20) face of the n-type substrate (2) of a high impurity concentration made of a tetragonal or rhombohedral silicon carbide single crystal.

15. A semiconductor device according to claim 9, wherein said n-type silicon carbide layer (3) of a low impurity concentration is formed on a (11-20) face of the n-type substrate (2) of a high impurity concentration made of a tetragonal or rhombohedral silicon carbide single crystal.

16. A semiconductor device according to any one of claims 1 to 4, wherein said n-type silicon carbide layer (3) of a low impurity concentration is formed on a (000-1) face of the n-type substrate (2) of a high impurity concentration made of a tetragonal or rhombohedral silicon carbide single crystal.

17. A semiconductor device according to claim 5, wherein said n-type silicon carbide layer (3) of a low impurity concentration is formed on a (000-1) face of the n-type substrate (2) of a high impurity concentration made of a tetragonal or rhombohedral silicon carbide single crystal.

18. A semiconductor device according to claim 6, wherein said n-type silicon carbide layer (3) of a low impurity concentration is formed on a (000-1) face of the n-type substrate (2) of a high impurity concentration made of a tetragonal or rhombohedral silicon carbide single crystal.

19. A semiconductor device according to claim 7, wherein said n-type silicon carbide layer (3) of a low impurity concentration is formed on a (000-1) face of the n-type substrate (2) of a high impurity concentration made of a tetragonal or rhombohedral silicon carbide single crystal.

20. A semiconductor device according to claim 8, wherein said n-type silicon carbide layer (3) of a low impurity concentration is formed on a (000-1) face of the n-type substrate (2) of a high impurity concentration made of a tetragonal or rhombohedral silicon carbide single crystal.

21. A semiconductor device according to claim 9, wherein said n-type silicon carbide layer (3) of a low impurity concentration is formed on a (000-1) face of the n-type substrate (2) of a high impurity concentration made of a tetragonal or rhombohedral silicon carbide single crystal.
